(19) United States
(12) Patent Application Publication
(10) Pub. No.: US 2026/0031287 A1
(43) Pub. Date: Jan. 29, 2026

(54) Method for Determining a Health Condition of an Electrical Device Comprising a Mechanical Actuation System

(71) Applicant: ABB Schweiz AG, Baden (CH)

(72) Inventors: Marco Cilibrasi, Zurich (CH); Kai Hencken, Lörrach (DE)

(73) Assignee: ABB Schweiz AG, Baden (CH)

(21) Appl. No.: 19/283,531

(22) Filed: Jul. 29, 2025

(30) Foreign Application Priority Data
Jul. 29, 2024 (EP) 24191430

(51) Int. Cl. H01H 11/00; G01R 31/327

(52) U.S. Cl. CPC H01H 11/0062; G01R 31/3274

(57) ABSTRACT

A method for determining a health condition of an electrical device comprising a mechanical actuation system includes obtaining measurement data indicative of a measured travel curve of the mechanical actuation system; obtaining model data indicative of a modeled travel curve of the mechanical actuation system in the electrical device, the model data being based on a mechanical model of the mechanical actuation system; and determining the health condition of the electrical device based on the measurement data and the model data.

### CROSS-REFERENCE TO RELATED APPLICATIONS

The instant application claims priority to European Patent Application No. 24191430.8, filed Jul. 29, 2024, which is incorporated herein in its entirety by reference.

### FIELD OF THE DISCLOSURE

The present disclosure generally relates to systems and methods for determining health conditions in electrical devices with mechanical actuation systems such as circuit breakers, switches, contactors, and the like.

### BACKGROUND OF THE INVENTION

In the field of determining health conditions in electrical devices with mechanical actuation systems, usually, data-driven techniques are applied, due to the large amount of data collected and the complex response of an overall travel curve of the mechanical actuator under degradation or faulty behavior. An example is the identification of some main features or characteristics of the travel curves, which are then used for classification, or for studying their evolution. This approach succeeds in detecting the fault or aging of the electrical device but fails in identifying the specific components responsible. It is also rather difficult to use it beyond fault detection, and to determine critical bounds.

Other approaches involve the analysis of the oscillations in the signal via Fourier transform, or also the identification of the main modes via a Principal Component Analysis. All these purely data-driven approaches, meaning models that are data-driven, but that take the physical nature of the system into account only indirectly, do not give satisfactory results, especially because they are not easy to interpret, do not give insight into the precise characterization of the different parts of the device, or do not allow to make predictions of the future evolution of the system.

Mechanical-based models, where a “digital twin” of the electrical device is produced with different levels of complexity, may give deeper understanding of the health condition of the electrical device.

However, one of the reasons why up to now a direct fitting of a model has not been attempted is due to the complexity of such models if they are based on real geometries or CAD files. This leads to issues in the identifiability of the parameters and means that many different changes to the system can lead to the same change in the travel curve, which makes any parameter fitting approach not viable.

### BRIEF SUMMARY OF THE INVENTION

The present disclosure generally relates to determining health conditions in electrical devices with mechanical actuation systems such as circuit breakers, switches, contactors, and the like. In particular, the disclosure relates to prognostics and health management of electrical devices, especially mechanical actuators, where the opening and closing operation of the contacts is often measured and analyzed, but it applies to any electrical device whose motion or, in other words, actuation is measured. Specifically, the present invention relates to a method for determining a health condition of an electrical device comprising a mechanical actuation system, a computer program product, and a data processing system.

According to an aspect of the present disclosure, there is provided a method for determining a health condition of an electrical device comprising a mechanical actuation system, the method comprising: obtaining measurement data indicative of a measured travel curve of the mechanical actuation system; obtaining model data indicative of a modeled travel curve of the mechanical actuation system in the electrical device, the model data being based on a mechanical model of the mechanical actuation system; and determining the health condition of the electrical device based on the measurement data and the model data.

### BRIEF DESCRIPTION OF THE SEVERAL VIEWS OF THE DRAWING(S)

FIG. 1 is a diagram of an electrical system in accordance with the disclosure.

FIG. 2 is a flowchart for a method for determining a health condition of an electrical device of the electrical system of FIG. 1.

FIG. 3 is a diagram of a mechanical actuation system of the electrical device of the electrical system of FIG. 1.

FIG. 4 is a graph of a measured travel curve and a modelled travel curve for the electrical system of FIG. 1.

FIG. 5 is a graph of a predicted travel curve for the electrical system of FIG. 1.

### DETAILED DESCRIPTION OF THE INVENTION

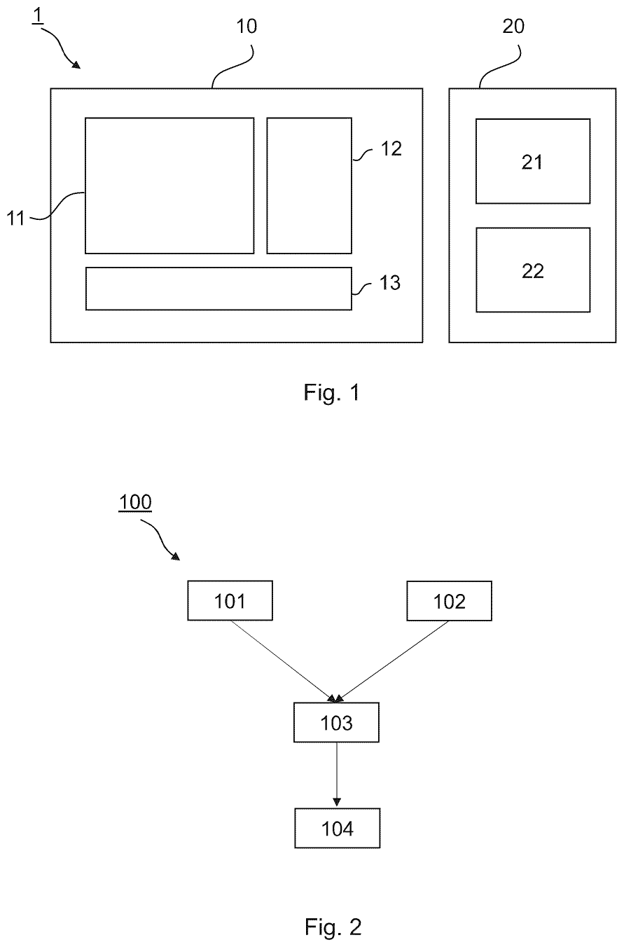

FIG. 1 schematically shows an electrical system 1 exemplary comprising an electrical device 10 with a mechanical actuation system 11 and a measuring unit 12. Further, in this example, the electrical device 10 comprises an electrical part in the form of an electrical contact 13. The mechanical actuation system 11 may be configured to close and open the electrical contact 13 of the electrical device 10. Hence, for example, the electrical device 10 may be in the form of a circuit breaker, contactor or switch but is not limited to these examples. Alternatively, the electrical contact 13 may be any other electrical part of the electrical device 10.

The measuring unit 12 may be configured to obtain measurement data indicative of a measured travel curve 1 of the mechanical actuation system 11 (see FIG. 4). The measured travel curve may be a travel path measured as a distance, e.g., in meters, millimeters or similar, over time, e.g., measured in seconds, milliseconds or similar (see FIG. 4). For this purpose, the measuring unit 12 may measure the travel path of at least one moving mechanical part or portion of the mechanical actuation system 11 over time. Generally, or depending on the type of actuation movement any one of a rotary encoder, a linear encoder, a position sensor, or an optical sensor but not limited thereto may be used as measurement unit 12.

A data processing system 20 may be part of the electrical system 1. The data processing system 20 may be connected to the electrical device 10, e.g., via a wire or wirelessly, in particular to the measuring unit 12 of the electrical device for obtaining the measurement data therefrom.

The data processing system 20 may comprise a data processing device 21, in particular in the form of a processing or computing unit or a processor and a computer, and/or a computer program product 22, e.g., in the form of a computer program as such or in the form of a computer-readable storage medium, having stored thereon the computer program. When the computer program product 22 is executed by the data processing device 21, the method 100 shown in FIG. 2 is executed.

One background of the method 100 is that electrical devices 10 such as the one of FIG. 1 include mechanical actuation systems 11 that are subjected to wear and thus degradation over their lifetime. Accordingly, their health condition may change over time. Specifically, the electrical devices 10 may fail over time or generally develop faulty conditions. To avoid replacing healthy electrical devices 10 and determine poor health conditions which may lead to a fault too early, it is desirable to determine the health condition of such electrical devices 10.

FIG. 2 schematically and exemplary illustrates a method 100 solving the aforementioned. Namely, the method 100 may be for determining a health condition of the electrical device 11. The health condition, in particular a fault condition, may be associated with or relate to a degraded or aged state, in particular but not only in terms of wear in one or more mechanical parts or elements of the mechanical actuation system 11 due to its mechanical working principle. As such, a fault does not necessarily need to occur and be recognized as such. However, early recognition of a poor health condition or fault condition, i.e., that the electrical device 10 may experience the fault, may be beneficial, because then the electrical device 10 may be repaired, replaced or similar before an actual fault occurs based on its fault condition.

For this purpose, the method 100 comprises, in a step 101, obtaining measurement data. The measurement data may be indicative of the measured travel curve 1 of the mechanical actuation system 11. FIG. 4 shows the measured travel curve 1 in the form of or, in other words, with its measured data points of travel (path) in meter over time in seconds, and exemplary for the opening of the electrical contact 13. Alternatively, or additionally, the measured travel curve 1 may be for the closing of the electrical contact 13. The measurement data may be obtained by the measurement unit 12 and/or the data processing system 20, e.g., the measurement data being forwarded from the measurement unit 12 to the data processing system 20. The measurement data may accordingly represent, reflect and/or comprise a travel curve of a travel path of a mechanical part of the mechanical actuation system 11 over time of the operation of the electrical device 10.

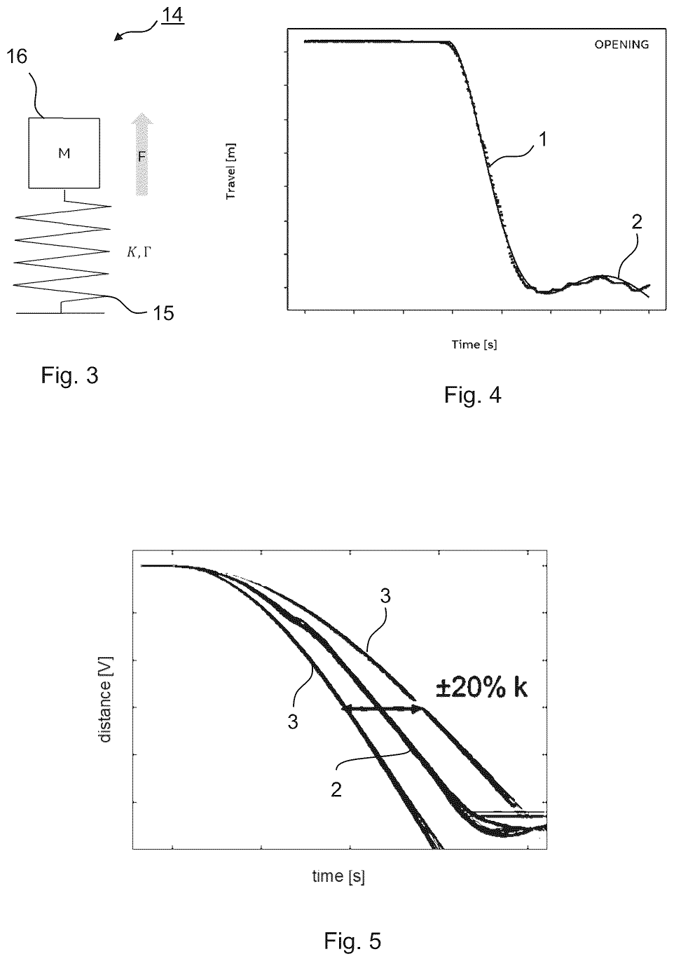

Further, the method 100 comprises, in a step 102, obtaining model data indicative of a modelled travel curve of the mechanical actuation system 11 in the electrical device 10, the model data being based on a mechanical model 14 of the mechanical actuation system 11 (see FIG. 3). The model data may be obtained, in particular determined, more particularly modelled, by the data processing system 20. The step 102 may be carried out before, after or simultaneously to step 101 of the method 100.

In particular, the mechanical model 14 or, generally, the model data may be based on a low-dimensional system of ordinary differential equations. For example, two or more, e.g., up to twenty or ten, ordinary differential equations may be part of the low-dimensional system. Hence, the mechanical model 14 may be a simplified mechanical model compared to more complex CAD or FEM models of the electrical device 10, for example. More specifically, the mechanical model 14 may be predominantly based on mechanical parameters which are influencing the travel curve 1 as measured of the mechanical actuation system 11.

For example, the mechanical model 14 may be comprising a number of mechanical parameters of the mechanical actuation system 11 in the range of 5 to 100, further simplifying the mechanical model and making it identifiable such that the mechanical parameters have a strong correlation to the modelled travel curve 1. Also, the mechanical actuation system 11 may be comparatively simple in that it has e.g. a number of degrees of freedom in the range of 1 to 10, specifically 1 to 5, and/or modelling the mechanical actuation system 11, specifically its mechanical parts or generally its actuation mechanism, with few simple mechanical elements, such as but not limited to any one or more of an elastic element, a non-elastic element, a spring, a damper, a mass, a friction element, or a connection element.

An exemplary mechanical actuation system 11 is illustrated In FIG. 3. This mechanical actuation system 11 may be modelled using several mechanical elements, e.g., two spring elements 15 and two masses 16 as shown in FIG. 3. The resulting mechanical model 14 may be indicative of a modelled travel curve for the mechanical actuation system 11, which may be a computer-generated travel curve rather than the actual or measured travel curve 1 seen in FIG. 4 and being indicative of the health state or condition of the electrical device 10.

In a step 103 of method 100, which may follow steps 101 and 102, the health condition may be determined, based on the measurement data and the model data. Step 103 may be carried out by the data processing system 20.

For example, the determination of the health condition in step 103 may comprise adapting the modelled travel curve to an adapted modelled travel curve 2 as seen in FIG. 4 to reproduce the measured travel curve 1, in particular as precisely as possible as may be seen in FIG. 4, where the adapted modelled travel curve 2 substantially fits or reproduces the measured travel curve 1. In other words, the step 103 may comprise that the modelled travel curve is fitted to represent the measured travel curve 1. The modelled travel curve and the adapted model travel curve 2 may be for the opening and/or closing of the electrical contact 13.

In this way, the mechanical model 14 with its mechanical parameters is optimized to reproduce or represent the actual or measured travel curve 1 of the mechanical actuation system 11. Hence, the mechanical model 14 represents as closely as possible or, in other words, as accurately as possible the current health condition or state of the mechanical actuation system 11. Hence, the mechanical parameters of the mechanical model 14, at least or specifically the ones which are influencing the travel curve, may be used in order to assess the health condition, since these are indicative for the health condition.

Consequently, the method 100 may comprise in step 103 or generally for the determination of the health condition, that the health condition is determined based on the adapted modelled travel curve 2, specifically its, or the mechanical model's 14 mechanical parameters, which are indicative for the health condition. Examples of such mechanical parameters are shown in FIG. 3 next to the exemplary mechanical elements in the form of spring constants K1, K2, masses Ma, Mb and/or force F. In this way, based on the mechanical parameters determined for the mechanical model 14 to reproduce or fit the measured travel curve 1, the health condition may be determined, specifically the degradation or wear of the mechanical parts of the mechanical actuation system 11 and if it may be necessary to replace or repair the electrical device 10 now or any time soon.

Also, or alternatively, it may be possible to predict a future health condition of the electrical device 10 based on the adapted modelled travel curve 2. For this purpose, one or more mechanical parameters of the adapted model data or, in other words, adapted modelled travel curve 2, may be altered in order to represent one or more predicted modelled travel curves 3 as exemplary shown in FIG. 5. For example, the mechanical parameters may be changed to predict the health condition after 100, 1000 or more mechanical actuations, by means of which due to wear e.g. a friction or similar in the mechanical actuation system 11 may increase and thus the health condition may be worsened.

Specifically, FIG. 5 shows such two exemplary predicted modelled travel curves 3. In the example of FIG. 5, compared to the adapted modelled travel curve 2 of FIG. 4, one or more of the mechanical parameters, specifically one or more of the spring constants K in this example, have been decreased and increased by exemplary 20%, to arrive at two predictions in form of a left predicted modelled travel curve 3 and a right predicted modelled travel curve 3. Hence, the prediction represents a scenario of degradation over time of one or more of the mechanical parts or elements, in particular spring elements, of the mechanical actuation system 11 within a bandwidth prediction of 20% decrease and increase of the spring constant K.

Specifically, in a detailed example, the method 100 has been applied to low and/or medium voltage circuit breakers, containing actuation mechanics for a typical medium voltage breaker as the electrical devices 10. In this case, the device structure for the mechanical model 14 has been simplified as exemplary shown in FIG. 3. For example, assuming constant geometry and stiff components, the motion may be described by only one or two dynamic variables, depending on whether constraints are active or not, as most of the mechanical elements can be treated as rigidly connected. The description is then in the form of a low-order dynamic system, with different dynamic equations for different parts of the motion.

The method 100 models the mechanism via a system of parametric ordinary differential equations, where each variable may describe one of the degrees of freedom of the mechanical actuation system 11. The mechanical actuation system 11, such as in a low or medium voltage circuit breaker, including their geometric constraints, may be modelled via analytical equations. The mechanical parameters represent the properties or features of the electrical device 10 itself. A model of a circuit breaker mechanism suitable for this method is the exemplary one shown in FIG. 3, where one mass 14 is connected to one damped spring and to a fixed frame. Here, the mass describes the inertia of the drive mechanism, the main shaft, and the levers to the push rods. The spring 15 attached to the fixed frame describes the opening spring. As only one travel curve is measured in this example, the three phases may be combined into a common one. This mechanical actuation system 11 is described by ordinary differential equations, which can be solved analytically or numerically. In particular, we have

$$M \ddot{x} = - K ( x - {x}_{0} ) - Γ \dot{x} + F$$

where x is the position of the mass M, K is the spring constant, Γ is the damping coefficient, x₀ the unstretched length of the spring. F describes the additional force applied by the closing spring to initiate the closing operation. The system includes also a model for the collision between the push rod and the fixed contact as an inelastic collision. Quantities may be normalized by factoring out the mass, i.e. K=Mk and Γ=M γ. In this way, the system 11 can become identifiable.

Despite being a very simple mechanical model 14, it does reproduce the data very well as seen in FIG. 4 when fitted to it. The parameter values from the fit give a clear estimate of the health condition of the electrical device 10, and their change in time is useful to track aging and detect faults. Thanks to its simplicity, the mechanical model is very fast and robust to fit and easy to interpret, proving to be an extremely effective method.

This approach has been tested with both normal aging and fault cases, giving always satisfactory results in detecting parameters and determining their evolution. In addition, such systems 11 are accessible to a formal determination of their identifiability with respect to the mechanical parameters. Sometimes this may not be possible. Only specific combinations of mechanical parameters can be uniquely identified, so only those are incorporated in the mechanical parameter set. Alternatively, physical parameters, that are expected to be fixed and not change during degradation, may be fixed in the ordinary differential equations.

Such a reduction of the mechanical system to one that is identifiable can be done with the help of available tools or methods. These are based e.g. starting from multi-body simulation. An alternative is the formulation of a Lagrangian function incorporating geometry and linked motion. Whereas such tools answer the question of (global) identifiability, the practical one may be checked as well. This can be done using simulation studies. Due to the linear nature of the mass-spring-damper system, the general mathematical theory is applicable. This is more complex in case of a generalization to a non-linear one.

Parameter estimation may follow the usual optimization approach. The simplest one is the (nonlinear) Least-Square approach. More complex ones, incorporating the knowledge of parameter ranges are helpful to improve the overall accuracy and robustness of the fit, but also aiding in the interpretation.

Compared to data-driven method, the method 100 has the advantage of connecting changes in the travel curve to specific changes in the device parameters. On the other hand, more complex multi-body models are better at capturing the details of the travel curves but are in general too complex to be identifiable, leading to difficulties in both their interpretation and predictive capabilities.

In addition, the simplified model has the capability to predict the behavior (travel curve) of the device 10 for other parameter values, especially the expected future form from the extrapolation of the current evolution, as described herein. This brings some advantages, as the parameters are evolving in a physical meaningful way. The extrapolated travel curves are more realistic, as they are based on the underlying laws of physics. By comparing these future travel curves, with limits imposed by the system in terms of speed or position, it can be judged whether they are out of range and therefore the end-of-life can be estimated.

In the context of the present disclosure, the method of may be an at least partially or fully computer implemented method. This means that at least one, multiple or all of the steps of the method may be carried out by a data processing system, which may comprise one or more computers or computing units, which may be part of the electrical device or not, e.g., integrated therewith or connected thereto. Different steps may be carried out by the same or by different computers. A computer is herein understood as a data processing apparatus or device, which can carry out some, multiple or all steps as defined by the method. Specifically, the obtaining of the measurement data, the model data and/or determining of the health condition may be carried out by the data processing system. Additionally, or alternatively, the obtaining of the measurement data may be carried out by a measurement device or system, which may optionally forward the measurement data to the data processing system such that it may obtain the measurement data.

The disclosure proposes a new condition monitoring technique based on the use of a mechanical model, in particular a parametric mechanic model, for a mechanical actuation system within an electrical device, such as a circuit breaker. Throughout their lifespan, electrical devices are susceptible to faults arising from both electrical and mechanical wear. The method enables to correlate measurement data, especially the travel curve, with physical parameters that model the electrical device and determine the health condition, in particular to indicate a location and/or nature of aging and failures of the electrical device.

The method of the first aspect of this disclosure thus allows for accurate determination of a health condition of a mechanical actuation system, in particular a mechanical actuator or parts thereof, by using a measured travel curve and a modelled travel curve of the mechanical actuation system, wherein the modelled travel curve is based on a mechanical model of the mechanical actuation system, and the model data may be particularly simple, e.g., by basing the model data on a low-dimensional system of ordinary differential equations.

The use of a simple mechanical model, which in particular is modelled in a suitable simplified way to make parameter estimation possible is an effective technique for determining the health condition. Such a simplified modelling may for example be enabled by having the model data or mechanical model based on a low-dimensional system of ordinary differential equations (ODE) rather than complex models based on real geometries or CAD files, where the geometry is used in order to describe the functional form. Specifically, complex multi-body or even FEM model need numerical solvers and are therefore often computationally very demanding and may be too demanding in comparison to the proposed simplified mechanical model. Alternatively, one can start with a formulation of a Lagrangian that allows to reduce the number of dynamical variables (degrees of freedom) taking into account geometric constraints but also simplifying the system overall. We can also make use of reduced-order models that are derived by using a larger amount of either experimental data or detailed simulation models (for example, multi-body simulations). Further, the mechanical model may be chosen to be identifiable with respect to its parameters, in particular mechanical parameters, and/or features, meaning that the modelled travel curve may be uniquely related to the parameters, in particular mechanical parameters, and/or features of the mechanical actuation system. This is in general not possible for more complex models and therefore does not allow them to be used in this way from a fundamental point of view. Such a reduction of the mechanical actuation system to one that is identifiable may be done with the help of available tools or methods, which are well known in the dynamic systems literature.

Making use of this simple mechanical model in the method, a mechanical parameter and/or feature estimation is possible in a robust way (“structural” and “practical” identifiability). The suggested approach is therefore effective in identifying meaningful (i.e., with respect to the travel curve) mechanical parameters of the mechanical actuation system and follow them in time. In this way, changes in the mechanical actuation system, for example, e.g. to the geometry, spring constants or damping coefficients of the mechanical actuation system, are followed and may be easily connected to degradation processes of the electrical device. They may also be used to predict the future evolution of the mechanical actuation system, hence predict when it will reach critical conditions. This generative nature of the model makes it more useful compared to current methods, that are based on outlier detection, as the end of life of the electrical device is linked to the future travel curve and not some threshold parameter, that is difficult to determine, especially in a multi-dimensional space.

For example, the determining of the health condition may comprise adapting the modeled travel curve to reproduce the measured travel curve. Also, the determining of the health condition may comprise determining the health condition based on the thereby acquired adapted modeled travel curve (acquired by means of the adapting of the modeled travel curve to reproduced the measured travel curve). In other words, the method may comprise adapting the modeled travel curve to reproduce the measured travel curve or, in other words, fitting the modeled travel curve to the measured travel curve, for determining the health condition. In this way, it may be ensured that the adapted modeled travel curve reproduces the measured travel curve as good as possible and allows to consequently determine the health condition based on the mechanical parameters of the modeled travel curve, which are indicative for the health condition.

In an example, the method may further comprise predicting a future health condition of the electrical device based on the adapted modeled travel curve by altering or, in other words, modifying one or more mechanical parameters of the model data. Accordingly, the adapted model data with its adapted modeled travel curve has not merely the capability or allows for determining a current health condition but also has the capability or allows to predict the behavior (predicted modeled travel curve) of the mechanical actuation system and thus its future health condition. For this purpose, one or more mechanical parameters of the model data may be modified or, in other words, altered. Specifically, an evolution of the one or more mechanical parameters may be extrapolated over time, thereby altering the one or more mechanical parameters, and yielding a predicted modeled travel curve, from which the health condition in the future may be determined. This brings some advantages, as the one or more mechanical parameters are evolving in a physical meaningful way. The extrapolated modeled travel curve with the altered one or more mechanical parameters are very realistic, as they are based on the underlying laws of physics. Specifically, by comparing the predicted modeled travel curve with one or more limits imposed by the mechanical actuation system in terms of speed or position, it can be judged whether they are out of range or not, and therefrom the end-of-life may be estimated.

In an example, the mechanical model, in particular the adapting of the modeled travel curve to reproduce the measured travel curve, may be predominantly based on mechanical parameters influencing the travel curve of the mechanical actuation system. In other words, the adapting or modeling mostly or optionally only includes those mechanical parameters that have an influence on the travel curve of the mechanical actuation system. This further allows that the modelled travel curve may be uniquely related to the relevant mechanical parameters and thus be identifiable.

In an example, the mechanical model may be comprising a number of degrees of freedom in the range of 1 to 10, in particular in the range of 1 to 5. The degrees of freedom are in particular mechanical degrees of freedom with respect to the mechanical or actuation movement of the mechanical parts or elements of the actuation system. Hence, the mechanical model is particularly simple and allows to easily determine the health condition.

In an example, the mechanical model may be comprising a number of mechanical parameters of the mechanical actuation system in the range of 2 to 100, in particular in the range of 5 to 80, more particularly in the range of 7 to 50. Hence, the mechanical model is particularly simple and allows to easily determine the health condition.

In an example, the mechanical model may be modeling the mechanical actuation system with one or more of: an elastic element, a non-elastic element, a spring, a damper, a mass, a friction element, or a connection element. Generally, the elastic element may be elastically extended or tensioned from a starting position and move back to the starting position elastically, while the non-elastic element may be static and not extended or tensioned elastically. Additionally, the mechanical model may be modeled including one or more other features, e.g., constraints, of the actuation motion, e.g., geometrical constraints, material constraints, and similar.

In an example, the measured travel curve may be indicative of a travel path of the mechanical actuation system over time. Thus, the measured travel curve may also be indicative of a degradation of the travel path of the mechanical actuation system over time since the travel path over time will typically change with the wear of the mechanical actuation system over time of usage. The travel path is a physical path of the mechanical actuation system e.g. in millimeters and may be recorded over time, for example, milliseconds, by a measurement system or unit.

In an example, the mechanical actuation system may be configured to mechanically close or open an electrical contact of the electrical device. For this purpose, the mechanical actuation system may be configured to travel a path over time between a closed and open position, in which the electrical contact is closed or opened.

In an example, the electrical device may be from one of: a circuit breaker, a switch, and a contactor.

In an example, the measurement data may be obtained from a measurement unit of the electrical device. The measurement unit may for example be one or more of: a rotary encoder, a linear encoder, a position sensor, or an optical sensor. Specifically, the measurement unit may depend on the type of actuation or actuation motion that is being carried out by the mechanical actuation system. For example, in case of a rotary actuation motion by the mechanical actuation system to open or close an electrical contact of the electrical device, the measurement unit may be a rotary encoder, which may measure or record the travel path of the mechanical actuation system, including one or more mechanical parts such as a contact thereof, over time, resulting in the measured travel curve of the mechanical actuation system.

According to a second aspect of this disclosure, there is provided a computer program product comprising instructions which, when the program is executed by a data processing system, cause the data processing system to carry out the method according to the first aspect of this disclosure.

The computer program product may be a computer program as such, meaning a computer program consisting of or comprising a program code to be executed by the computer.

Alternatively, the computer program product may be a product such as a data storage, in particular a computer-readable data storage medium, on which the computer program may be temporarily or permanently stored.

According to a third aspect of this disclosure, there is provided a data processing system configured to carry out the method according to the first aspect of this disclosure.

The data processing system may comprise one or more computers as previously described and, optionally, the computer program product of the second aspect of this disclosure.

According to a fourth aspect of this disclosure, there may be provided an electrical system comprising an electrical device comprising a mechanical actuation system and a measurement unit, and the data processing system of the third aspect of this disclosure.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method for determining a health condition of an electrical device comprising a mechanical actuation system, the method comprising:
obtaining measurement data indicative of a measured travel curve of the mechanical actuation system;
obtaining model data indicative of a modeled travel curve of the mechanical actuation system in the electrical device, the model data being based on a mechanical model of the mechanical actuation system; and
determining the health condition of the electrical device based on the measurement data and the model data.

2. The method of claim 1, wherein the model data is based on a low-dimensional system of ordinary differential equations.

3. The method of claim 1, wherein the determining of the health condition comprises adapting the modeled travel curve to reproduce the measured travel curve and determining the health condition based on the adapted modeled travel curve.

4. The method of claim 3, wherein the method further comprises predicting a future health condition of the electrical device based on the adapted modeled travel curve by altering one or more mechanical parameters.

5. The method of claim 3, wherein adapting the modeled travel curve is based on mechanical parameters influencing the travel curve of the mechanical actuation system.

6. The method of claim 1, wherein the mechanical model comprises between 1 and 10 degrees of freedom.

7. The method of claim 1, wherein the mechanical model comprises between 2 and 100 mechanical parameters of the mechanical actuation system.

8. The method of claim 1, wherein the mechanical model modeling the mechanical actuation system includes one or more of: an elastic element, a non-elastic element, a spring, a damper, a mass, a friction element, and a connection element.

9. The method of claim 1, wherein the measured travel curve is indicative of a travel path of the mechanical actuation system over time.

10. The method of claim 1, wherein the mechanical actuation system is configured to mechanically close or open an electrical contact of the electrical device.

11. The method of claim 1, wherein the electrical device is one of a circuit breaker, a switch, and a contactor.

12. The method of claim 1, wherein the measurement data is obtained from a measurement unit of the electrical device.

13. The method of claim 12, wherein the measurement unit is one or more of: a rotary encoder, a linear encoder, a position sensor, and an optical sensor.

14. A computer program product comprising instructions which, when executed by a data processing system, cause the data processing system to carry out a method for determining a health condition of an electrical device comprising a mechanical actuation system, comprising:
instructions for obtaining measurement data indicative of a measured travel curve of the mechanical actuation system;
instructions for obtaining model data indicative of a modeled travel curve of the mechanical actuation system in the electrical device, the model data being based on a mechanical model of the mechanical actuation system; and
instructions for determining the health condition of the electrical device based on the measurement data and the model data.

15. The computer program product of claim 14, wherein the model data is based on a low-dimensional system of ordinary differential equations.

16. The computer program product of claim 14, wherein the determining of the health condition comprises adapting the modeled travel curve to reproduce the measured travel curve and determining the health condition based on the adapted modeled travel curve.

17. The computer program product of claim 16, further comprising instructions for predicting a future health condition of the electrical device based on the adapted modeled travel curve by altering one or more mechanical parameters.

18. The computer program product of claim 16, wherein adapting the modeled travel curve is based on mechanical parameters influencing the travel curve of the mechanical actuation system.

19. The computer program product of claim 14, wherein the mechanical model comprises between 1 and 10 degrees of freedom.

20. The computer program product of claim 14, wherein the mechanical model comprises between 2 and 100 mechanical parameters of the mechanical actuation system.
